(19) United States
(12) Patent Application Publication
(10) Pub. No.: US 2006/0237753 A1
(43) Pub. Date: Oct. 26, 2006

(54) Semiconductor device and method for manufacturing the same

(75) Inventors: Yoshiharu Anda, Uozu-shi (JP); Akiyoshi Tamura, Suita-shi (JP); Mitsuru Nishitsuji, Uozu-shi (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi (JP)

(21) Appl. No.: 11/388,545

(22) Filed: Mar. 24, 2006

(30) Foreign Application Priority Data
Apr. 25, 2005 (JP) JP2005-127020

(51) Int. Cl. H01L 31/112

(52) U.S. Cl. 257/280

(57) ABSTRACT

A field effect transistor according to the present invention includes a channel layer formed above a semi-insulating substrate, a Schottky layer formed above the channel layer, a gate electrode formed on the Schottky layer, Ohmic contact layers that are located above the Schottky layer with the gate electrode interposed therebetween and formed of InGaAs, and a source electrode and a drain electrode that are formed on the Ohmic contact layers. The source electrode, the drain electrode and the gate electrode have a layered structure in which their corresponding layers are formed of the same material, a lowermost layer is a WSi layer and a layer containing Al is provided above the lowermost layer. A field effect transistor that has an electrode resistance equivalent to a conventional level and can reduce a cost of manufacturing a field effect transistor and a method for manufacturing the same are provided.

### BACKGROUND OF THE INVENTION

1. Field of the Invention

The present invention relates to a semiconductor device, in particular, a field effect transistor and a method for manufacturing the same.

2. Description of Related Art

In recent years, field effect transistors (in the following, also referred to as FETs) using a compound semiconductor such as GaAs have been used widely in radio communication, in particular, power amplifiers and RF switches in mobile phone terminals, etc. Among these FETs, PHEMTs (pseudomorphic high electron mobility transistors) have especially excellent high-frequency characteristics. Further, PHEMTs also are used widely in semiconductor devices such as a monolithic microwave integrated circuit (MMIC) in which active elements such as FETs and passive elements such as a semiconductor resistor, a metal resistance element and a capacitor are integrated.

In this field, a manufacturing method with fewer processes also is required for reducing a manufacturing cost.

In PHEMTs, AlGaAs, which is known to have a high surface level density, generally is used for a Schottky layer. On the other hand, InGaP has a lower surface level density than AlGaAs and an excellent high-frequency response, and thus, the use of InGaP as the Schottky layer also is being studied. However, in this case, in order to suppress an interdiffusion of In contained in InGaP and a gate electrode material due to heat, WSi, which is a high-melting metal, or the like is used as the electrode. Since the electrode can be formed easily by a compound semiconductor process, JP 2004-260054 A, for example, describes PHEMT using an electrode including four layers of a WSi layer, a Ti layer, a Pt layer and an Au layer from the side of a Schottky layer.

FIG. 3 is a sectional view showing a sectional structure of the PHEMT using the electrode including the four layers of the WSi layer, the Ti layer, the Pt layer and the Au layer from the side of the Schottky layer. This PHEMT includes a layered body 109 formed on a semi-insulating GaAs substrate 101, element isolation regions 108, an insulator film 110 having openings formed on the layered body 109, a gate electrode 114 formed in the opening of the insulator film 110 and Ohmic electrodes 115 that are formed in the openings of the insulator film 110 and form a drain electrode and a source electrode.

The layered body 109 includes a buffer layer 102, an undoped In_{0.2}Ga_{0.8}As channel region 103, an n-type In_{0.25}Ga_{0.75}As carrier supply layer 104, an undoped Al_{0.25}Ga_{0.75}As Schottky layer 105, an n-type GaAs cap layer 106 and an n-type In_{0.5}Ga_{0.5}As Ohmic contact layer 107. Further, the gate electrode 114 and the Ohmic electrodes 115 respectively are formed of layered metal films 111a and 111b obtained by layering the WSi layer, the Ti layer, the Pt layer and the Au layer in this order from the side of the layered body 109, followed by patterning, and gold plating films 113a and 113b formed on the layered metal films 111a and 111b. Moreover, the Schottky layer 105 and the gate electrode 114 make a Schottky junction, and the Ohmic contact layer 107 and the Ohmic electrodes 115 make an Ohmic junction.

The following is a description of a method for manufacturing a PHMET having the configuration described above. FIGS. 4A to 4D are sectional views showing a process of manufacturing the PHMET having the above-described configuration.

As shown in FIG. 4A, the buffer layer 102, the channel region 103, the carrier supply layer 104, the Schottky layer 105, the cap layer 106 and the Ohmic contact layer 107 are grown in this order on the semiconductor substrate 101 by an epitaxial growth, thereby forming the layered body 109. Thereafter, an ion implantation is carried out in a predetermined region of the layered body 109, thus forming the element isolation regions 108. Further, the Ohmic contact layer 107 and the cap layer 106 in a gate formation region are subjected to dry etching so as to form an opening in the layered body 109. Subsequently, the insulator film 110 formed of SiO₂, SiN or the like is formed on the layered body 109 and the opening by plasma CVD.

Next, as shown in FIG. 4B, a photoresist film is deposited on the insulator film 110, followed by patterning. Then, dry etching is carried out using a mixed gas of a CHF₃ gas and an SF₆ gas, thereby forming contact holes for forming the Ohmic electrodes 115. Further, the WSi layer, the Ti layer, the Pt layer and the Au layer are deposited in this order on the insulator film 110 and the contact holes by sputtering, thereby forming the layered metal film 111.

Subsequently, as shown in FIG. 4C, a photoresist film 112 is formed and then patterned so that openings are provided at positions corresponding to the contact holes. Using this photoresist film 112 as a mask, the gold plating films 113a and 113b are formed. Then, this photoresist film 112 is removed.

Finally, as shown in FIG. 4D, the layered metal film 111 is subjected to dry etching using the gold plating films 113a and 113b as a mask, thus forming the Ohmic electrodes 115 and the gate electrode 114 formed of the gold plating films 113a and 113b and the patterned layered metal films 111a and 111b, respectively.

However, since the conventional field effect transistor described above uses the electrodes formed of the WSi layer, the Ti layer, the Pt layer and the Au layer, the material cost is high. Further, in general, different masks often are used for forming the source and drain electrodes using the Ohmic junction and forming the gate electrode using the Schottky junction. This serves as a factor increasing the manufacturing process cost. Therefore, it has been difficult to form the source, drain and gate electrodes simultaneously using a low-cost material.

### SUMMARY OF THE INVENTION

It is an object of the present invention to solve the problems described above and to provide a field effect transistor that has an electrode resistance equivalent to a conventional level and can reduce a cost of manufacturing a field effect transistor and a method for manufacturing the same.

A field effect transistor according to the present invention includes a channel layer formed above a semi-insulating substrate, a Schottky layer formed above the channel layer, a gate electrode formed on the Schottky layer, Ohmic contact layers that are located above the Schottky layer with the gate electrode interposed therebetween and are formed of InGaAs, and a source electrode and a drain electrode that are formed on the Ohmic contact layers. The source electrode, the drain electrode and the gate electrode have a layered structure in which their corresponding layers are formed of the same material, a lowermost layer is a WSi layer and a layer containing Al is provided above the lowermost layer. With this configuration, a field effect transistor with a drain electrode, a source electrode and a gate electrode that have a low electrode resistance can be manufactured at low cost.

Further, a method for manufacturing a field effect transistor according to the present invention includes forming a buffer layer on a semi-insulating substrate, forming a channel layer on the buffer layer, forming a Schottky layer above the channel layer, forming an Ohmic contact layer formed of InGaAs above the Schottky layer, providing an opening in a predetermined region in the Ohmic contact layer so as to expose the Schottky layer, forming an insulator film covering the exposed Schottky layer and the Ohmic contact layer, forming openings simultaneously in the insulator film at positions where a source electrode, a drain electrode and a gate electrode are to be formed, forming an electrode metal film in the openings in the insulator film, and etching a portion in the electrode metal film except for the positions where the source electrode, the drain electrode and the gate electrode are to be formed. The electrode metal film has a layered structure in which a lowermost layer is a WSi layer and a layer containing Al is provided above the lowermost layer

### BRIEF DESCRIPTION OF THE DRAWINGS

FIG. 1 is a sectional view showing a configuration of a field effect transistor in an embodiment of the present invention.

FIG. 2A is a sectional view showing a manufacturing process of the field effect transistor in the embodiment of the present invention.

FIG. 2B is a sectional view showing a process subsequent to the process shown in FIG. 2A.

FIG. 2C is a sectional view showing a process subsequent to the process shown in FIG. 2B.

FIG. 2D is a sectional view showing a process subsequent to the process shown in FIG. 2C.

FIG. 2E is a sectional view showing a process subsequent to the process shown in FIG. 2D.

FIG. 2F is a sectional view showing a process subsequent to the process shown in FIG. 2E.

FIG. 3 is a sectional view showing a configuration of a conventional field effect transistor.

FIG. 4A is a sectional view showing a manufacturing process of the conventional field effect transistor.

FIG. 4B is a sectional view showing a process subsequent to the process shown in FIG. 4A.

FIG. 4C is a sectional view showing a process subsequent to the process shown in FIG. 4B.

FIG. 4D is a sectional view showing a process subsequent to the process shown in FIG. 4C.

### DETAILED DESCRIPTION OF THE INVENTION

In the above-described field effect transistor according to the present invention, the source electrode, the drain electrode and the gate electrode also can be configured to have a first layer that contacts the Schottky layer or the Ohmic contact layer and is formed of WSi, a second layer that is provided above the first layer and formed of Ti, a third layer that is provided above the second layer and contains Al, and a fourth layer that is provided above the third layer and formed of Ti.

Alternatively, the source electrode, the drain electrode and the gate electrode also can be configured to have a first layer that contacts the Schottky layer or the Ohmic contact layer and is formed of WSi, a second layer that is provided above the first layer and formed of Cr, a third layer that is provided above the second layer and contains Al, and a fourth layer that is provided above the third layer and formed of Cr.

Also, it is preferable that the layer containing Al contains at least 0.1 atm % Ti. This configuration allows the layer containing Al to have an improved ability to withstand electro-migration.

Further, the Schottky layer also can be configured to contain In and P. With this configuration, thermal reliability improves.

Moreover, in the above-described method for manufacturing a field effect transistor according to the present invention, the Schottky layer also can contain In and P.

The following is a description of an embodiment of the present invention, with reference to the accompanying drawings.

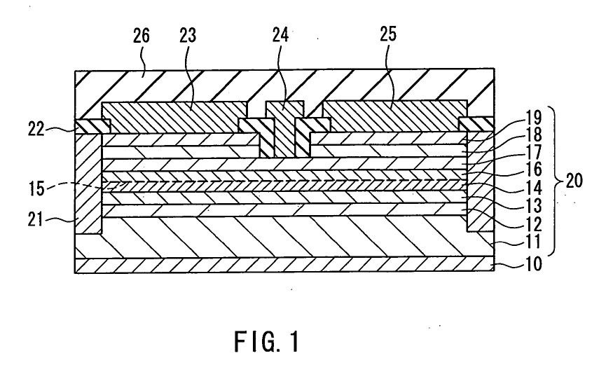

First, a configuration of a FET according to the present invention will be described. FIG. 1 is a sectional view showing a sectional configuration of the FET according to the present invention. On a substrate 10 formed of a semi-insulating GaAs, a 1 μm thick undoped GaAs first buffer layer 11 is formed for alleviating a lattice mismatch with the substrate 10. On the first buffer layer 11, a 100 nm thick undoped AlGaAs second buffer layer 12 is formed. On the second buffer layer 12, a 20 nm thick undoped In_{0.2}Ga_{0.8}As channel layer 13 is formed through which carriers move.

On the channel layer 13, a 5 nm thick first spacer layer 14 of undoped Al_{0.25}Ga_{0.75}As is formed, and then a 20 nm thick second spacer layer 16 also formed of undoped Al_{0.25}Ga_{0.75}As is provided thereon. Further, a carrier supply layer 15 that is planar-doped with Si, which is an n-type impurity ion, in a dosage amount of 5×10¹² cm⁻² so as to have a thickness corresponding to a single atomic layer is formed between the first spacer layer 14 and the second spacer layer 16.

On the second spacer layer 16, an undoped In_{0.48}Ga_{0.52}P Schottky layer 17 with a thickness of 10 nm is formed. On the Schottky layer 17 except for a position at which a base electrode is to be formed, an n⁺-type GaAs dope layer 18 with a thickness of 50 nm is formed, and then an n⁺-type InGaAs Ohmic contact layer 19 with a thickness of 50 nm functioning as a cap layer is formed thereon. It should be noted that the layers from the buffer layer 11 to the Ohmic contact layer 19 are formed by an epitaxial growth and collectively referred to as an epitaxial layer 20.

On the epitaxial layer 20, an insulator film 22 of Si₃N₄ or SiO₂ is formed. The insulator film 22 has openings at positions where a source electrode 23, a drain electrode 25 and a gate electrode 24 are formed. The source electrode 23 and the drain electrode 25 that make an Ohmic junction with the Ohmic contact layer 19 are provided in the openings in the insulator film 22 on the Ohmic contact layer 19. The gate electrode 24 that makes a Schottky junction with the Schottky layer 17 is provided in the opening in the insulator film 22 on the Schottky layer 17.

The source electrode 23, the drain electrode 25 and the gate electrode 24 have a layered structure including a WSi layer formed of WSi, a first Ti layer formed of Ti, an Al layer formed of Al and a second Ti layer formed of Ti in this order from the lowermost layer on the side of the epitaxial layer 20. The lowermost WSi layer is highly reliable in suppressing an interdiffusion with the InGaP layer 17 (the Schottky layer) due to heat and achieves an excellent Ohmic junction with the n⁺InGaAs layer 19 (the Ohmic contact layer).

Further, in the vicinity of the source electrode 23 and the drain electrode 25, element isolation regions 21 are formed for element isolation. Moreover, the source electrode 23, the drain electrode 25 and the gate electrode 24 are covered with an insulator film 26 formed of Si₃N₄ or SiO₂, for example.

With the above-described configuration, the source electrode 23, the drain electrode 25 and the gate electrode 24 have a structure of layering the WSi layer, the first Ti layer, the Al layer and the second Ti layer and achieves a resistance equivalent to that in the case of using Pt and Au. In addition, since Pt and Au are not used, it is possible to manufacture the field effect transistor at low cost.

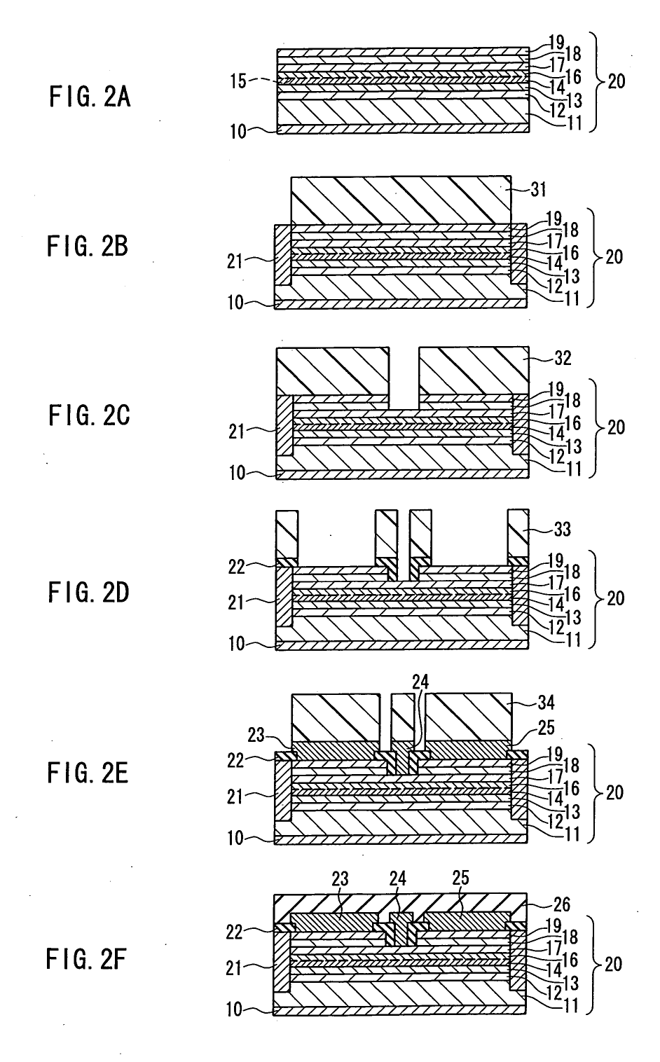

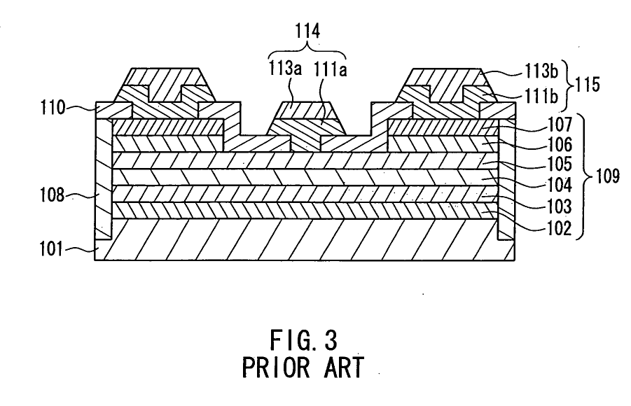

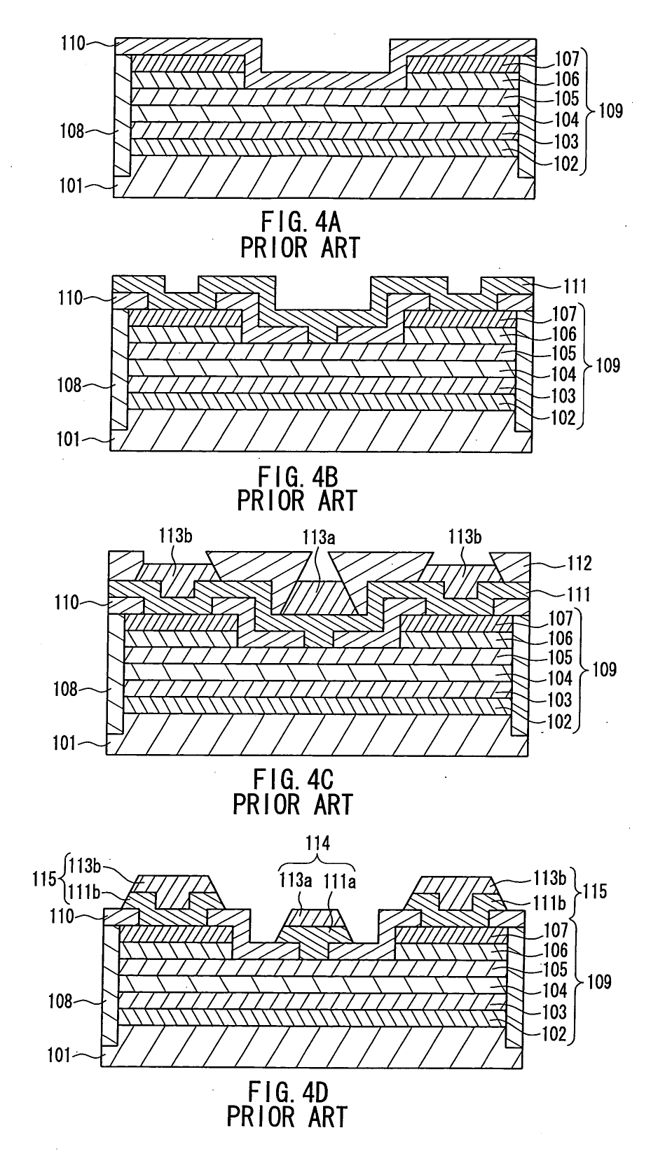

Now, a method for manufacturing the field effect transistor having the above-described structure will be described, with reference to FIG. 2. FIG. 2 is a sectional view showing a manufacturing process of the field effect transistor according to the present embodiment.

First, as shown in FIG. 2A, the first buffer layer 11, the second buffer layer 12, the channel layer 13, the first spacer layer 14, the carrier supply layer 15, the second spacer layer 16, the Schottky layer 17, the dope layer 18 and the Ohmic contact layer 19 are formed in this order on the semi-insulating GaAs substrate 10 by epitaxial growth using, for example, an MO-CVD method or an MBE method.

Next, as shown in FIG. 2B, a photoresist 31 is formed and patterned using photolithography or the like. Using this photoresist 31 as a mask, an ion implantation is carried out so as to form the element isolation regions 21. Incidentally, the element isolation also can be performed by mesa-etching predetermined positions in the epitaxial layer 20.

Subsequently, the photoresist 31 is removed, and as shown in FIG. 2C, a photoresist is formed and patterned so as to form an opening at a position where the gate electrode 24 is to be formed. Using this patterned photoresist 32 as a mask, etching is carried out so as to remove the Ohmic contact layer 19 and the dope layer 18, thereby exposing the Schottky layer 17.

Next, after the photoresist 32 is removed as shown in FIG. 2D, the Si₃N₄ insulator film 22 with a thickness of 300 nm is formed on the epitaxial layer 20, for example. Then, a photoresist is formed on the insulator film 22 and patterned so that openings are provided at positions where the source electrode 23, the drain electrode 25 and the gate electrode 24 are to be formed. Using this patterned photoresist 33 as a mask, the insulator film 22 located at the positions where the openings are to be formed is removed by dry etching. At this time, the dry etching might damage the exposed Schottky layer 17. Considering this, the dry etching preferably is carried out in such a manner as to minimize the damage.

Thereafter, as shown in FIG. 2E, the WSi layer, the first Ti layer, the Al layer and the second Ti layer are deposited on the wafer surface in this order from the wafer surface by sputtering or vapor deposition, thereby forming an electrode layer. At this time, by forming the electrode layer while optimizing the thickness of the Al layer having a high electrical conductivity, a predetermined resistance can be obtained. Also, at least 0.1 atm % Ti is contained in the Al layer, making it possible to improve a property to withstand electro-migration. Additionally, since the resistance rises with an increase in the addition amount of Ti contained in the Al layer, it is desired that the amount of Ti be not greater than 2 atm %.

Next, a photoresist is applied to the electrode layer and patterned to form a photoresist 34. Using this photoresist 34 as a mask, the electrode layer is etched using a chlorinated gas, thereby forming the source electrode 23, the drain electrode 25 and the gate electrode 24.

Then, the photoresist 34 is removed, and as shown in FIG. 2F, the insulating protective film 26 is formed so as to cover the source electrode 23, the drain electrode 25 and the gate electrode 24. By the processes described above, the field effect transistor according to the present embodiment is completed.

It should be noted that the source electrode 23, the drain electrode 25 and the gate electrode 24 according to the present embodiment can be used not only in PHEMTs using the GaAs substrate but also in all field effect transistors using an InGaAs Ohmic contact layer and an InGaP Schottky layer and further in field effect transistors using an InP substrate and those using InP for the Schottky layer.

With the configuration described above, the source electrode 23, the drain electrode 25 and the gate electrode 24 have a layered structure including the WSi layer, the first Ti layer, the Al layer and the second Ti layer, so that a low-cost field effect transistor without using Pt or Au can be manufactured.

Moreover, the source electrode 23, the drain electrode 25 and the gate electrode 24 also can have layers formed of Cr instead of the first Ti layer and the second Ti layer, respectively. With this configuration, it is possible to achieve an effect similar to that in the case of the layered structure including the WSi layer, the first Ti layer, the Al layer and the second Ti layer.

Also, another layer formed of TiN or the like may be present between the WSi layer and the first Ti layer.

In addition, it is preferable that the Al layer contains 90 to 100 atm % Al. The reasons follow. Several atm % to 10 atm % of impurities contained in the Al layer are sufficient for suppressing electro-migration. Also, an increase in the content of impurities lowers an electrical conductivity of the overall wiring and further impairs wirebility; for example, an alloy part of Al and impurity is difficult to etch.

Furthermore, by optimizing the thickness of the Al layer as the electrode, it is possible to obtain a predetermined resistance.

Also, the source electrode 23, the drain electrode 25 and the gate electrode 24 can be formed in a single process. Accordingly, the number of manufacturing processes can be reduced, making it possible to cut the manufacturing cost.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A field effect transistor comprising:
a channel layer formed above a semi-insulating substrate;
a Schottky layer formed above the channel layer;
a gate electrode formed on the Schottky layer;
Ohmic contact layers that are located above the Schottky layer with the gate electrode interposed therebetween and are formed of InGaAs; and
a source electrode and a drain electrode that are formed on the Ohmic contact layers;
wherein the source electrode, the drain electrode and the gate electrode have a layered structure in which their corresponding layers are formed of the same material, a lowermost layer is a WSi layer and a layer containing Al is provided above the lowermost layer.

2. The field effect transistor according to claim 1, wherein the source electrode, the drain electrode and the gate electrode comprise
a first layer that contacts the Schottky layer or the Ohmic contact layer and is formed of WSi,
a second layer that is provided above the first layer and formed of Ti,
a third layer that is provided above the second layer and contains Al, and
a fourth layer that is provided above the third layer and formed of Ti.

3. The field effect transistor according to claim 1, wherein the layer containing Al contains at least 0.1 atm % Ti.

4. The field effect transistor according to claim 2, wherein the layer containing Al contains at least 0.1 atm % Ti.

5. The field effect transistor according to claim 1, wherein the source electrode, the drain electrode and the gate electrode comprise
a first layer that contacts the Schottky layer or the Ohmic contact layer and is formed of WSi,
a second layer that is provided above the first layer and formed of Cr,
a third layer that is provided above the second layer and contains Al, and
a fourth layer that is provided above the third layer and formed of Cr.

6. The field effect transistor according to claim 1, wherein the Schottky layer contains In and P.

7. The field effect transistor according to claim 2, wherein the Schottky layer contains In and P.

8. The field effect transistor according to claim 3, wherein the Schottky layer contains In and P.

9. The field effect transistor according to claim 4, wherein the Schottky layer contains In and P.

10. The field effect transistor according to claim 5, wherein the Schottky layer contains In and P.

11. A method for manufacturing a field effect transistor, comprising:
forming a buffer layer on a semi-insulating substrate;
forming a channel layer on the buffer layer;
forming a Schottky layer above the channel layer;
forming an Ohmic contact layer formed of InGaAs above the Schottky layer;
providing an opening in a predetermined region in the Ohmic contact layer so as to expose the Schottky layer;
forming an insulator film covering the exposed Schottky layer and the Ohmic contact layer;
forming openings simultaneously in the insulator film at positions where a source electrode, a drain electrode and a gate electrode are to be formed;
forming an electrode metal film in the openings in the insulator film, the electrode metal film having a layered structure in which a lowermost layer is a WSi layer and a layer containing Al is provided above the lowermost layer; and
etching a portion in the electrode metal film except for the positions where the source electrode, the drain electrode and the gate electrode are to be formed.

12. The method for manufacturing a field effect transistor according to claim 11, wherein the Schottky layer contains In and P.
